(19) United States
(12) Patent Application Publication
(10) Pub. No.: US 2026/0308770 A1
(43) Pub. Date: Oct. 8, 2026

(54) VAPOR-PHASE ETCH OF METAL-CONTAINING MATERIALS

(71) Applicant: Versum Materials US, LLC, Tempe, AZ (US)

(72) Inventors: Martin McBriarty, San Jose, CA (US); Nguyen Vu, Santa Clara, CA (US); Bhushan Zope, San Jose, CA (US)

(21) Appl. No.: 19/474,828

(22) PCT Filed: Mar. 4, 2024
(86) PCT No.: PCT/US24/18342

§ 371 Date: Oct. 13, 2025

Related U.S. Application Data
(60) Provisional application No. 63/496,230, filed on Apr. 14, 2023.

(51) Int. Cl. C23F 1/02; C23F 1/12; H10P 50/26

(52) U.S. Cl. CPC C23F 1/02; C23F 1/12; H10P 50/266

(57) ABSTRACT

The disclosed and claimed subject matter relates to processes for performing selective thermal vapor-phase etching of metals, including Ti, Co, Ni, Cu, Mo, Ru, Ta and/or W, and compounds thereof, such as oxides, hydroxides, oxyhydroxides, carbonates, carbides, fluorides, or chlorides, which do not require the use of plasmas or halogenated volatilizing agents.

### CROSS REFERENCE TO RELATED APPLICATION(S)

This application claims the benefit of U.S. Provisional Patent Application No. 63/496,230 filed on Apr. 14, 2023, which is incorporated herein by reference as if fully set forth.

### BACKGROUND

### Field

The disclosed and claimed subject matter relates to a process for performing vapor-phase etching of films that include Co, Cu, Ni, Mo, or similar materials, using volatilizing agents which do not contain halogens. The disclosed and claimed subject matter further includes (1) a selective vapor-phase etching process in which a volatilizing agent is dosed to selectively etch a thin film of a material atop a substrate of a different material, and (2) a selective atomic layer etching (ALE) process in which a surface modification reactant is dosed prior to dosing the volatilizing agent which selectively etches the modified surface material. In both cases, the amount of material etched can be controlled by cycling the process multiple times.

### Related Art

The miniaturization of features in the semiconductor industry is the main factor behind the continuous performance increase of devices. This trend is expected to continue for at least a few more generations of computer chips. In this regard, existing methods for fabricating nanometer-scale components are reaching physical limits, and new chemical processes with high selectivity and atomic-layer precision are required.

In the fabrication of microelectronic logic devices, highly selective etches are required to precisely remove one material or set of materials from a surface with many exposed materials, including metals, dielectrics, and semiconductors. Metal etches are required particularly in the back end of line (BEOL) processes which define the interconnects between logic transistors and their peripheral devices, for which materials of interest include Co, Cu, Mo, Ru, W, TiN, and TaN. In some approaches to scaling down BEOL processes, such as the fully self-aligned via (FSAV) scheme, one metal or a set of metals must be selectively recessed by a few nanometers relative to a dielectric material following planarization of a patterned wafer. Any residues of the metal or etchants which remain on the dielectric material surface may harm the performance of the device; thus, it is desirable to cleanly, effectively, and selectively remove residues during and/or after an etch process.

Vapor-phase etching or cleaning methods are well-suited to this task. Vapor-phase methods can etch at smaller critical dimensions and with fewer residues than wet etches. Compared to plasma etches, vapor-phase etches may also be performed with less damage to exposed materials which are not intended to be etched. Thus, a vapor-phase etching or cleaning process is desired which will selectively remove one material or set of materials, such as thin metal oxide layers formed by metal exposure to atmosphere or oxidants. In some implementations, a vapor-phase etchant can be continuously dosed. In some implementations, there is one sequential dose-purge cycle which may be repeated.

Atomic Layer Deposition (ALD) is one technique finding increased application in the semiconductor industry and it currently is the deposition method allowing the best control on the amount of material deposited. In ALD, a layer of atoms is typically deposited on all surfaces that are exposed to a precursor in the gas phase—this layer is at most as thick as the thickness of one atomic layer. By sequentially exposing the surfaces to two different precursors, a layer of material with the desired thickness will be deposited. The archetypical example of such a process is the deposition of aluminum oxide (Al₂O₃) from trimethylaluminum (TMA, Al(CH₃)₃) and water (H₂O), in which methane (CH₄) is eliminated from the two reacting species. The coating of thin and narrow vias and other high aspect ratio features by ALD have been demonstrated numerous times in the literature.

Atomic Layer Etching (ALE or ALEt) can be viewed as the layer-by-layer subtraction of material when ALD is the layer-by-layer addition of material. In ALE, a layer of atoms is removed from all surfaces of a particular material, or a particular set of materials, that are exposed to a precursor in the gas phase; this layer is ideally also at most as thick as the thickness of one atomic layer. ALE is performed by sequentially exposing the surfaces to at least two different precursors: a 1^{st} precursor that activates a layer of surface atoms, and a 2^{nd} precursor that promotes the sublimation of this activated layer of atoms. The 1^{st} precursor may be referred to as a surface modification agent or surface modifier, and the 2^{nd} precursor may be referred to as a volatilizing agent or volatilizer. A 3^{rd} precursor is sometimes used to regenerate the surface to the condition where the 1^{st} precursor will be active.

As noted above, isotropic ALE involves repeated cycles of dosing a reactant into a vacuum chamber which contains work piece to be etched, then purging the chamber to remove an excess of the reactant and any reaction products. In some implementations, there are two sequential dose-purge sub-cycles, each with a different reactant or combination of reactants. In some implementations, there are three or more sequential dose-purge sub-cycles, each with a different reactant or combination of reactants.

Cobalt (Co) and its alloys are considered promising materials for use in the middle-of-line (MOL) and back-end-of-line (BEOL) processing of semiconductor logic and memory devices, whether as the primary conductive line material, or as a liner or barrier between another conductive line material and an interlayer dielectric (ILD). Other metals of interest for such applications include Cu, Mo, Ru, W, TiN, and TaN.

Several cobalt etching procedures have been described. See, e.g., Zhao et al., Applied Surface Science, 455, 438 (2018); Konh et al., Journal of Vacuum Science & Technology A, 37, 021004 (2019); Wang et al., Journal of Vacuum Science & Technology A, 38, 022611 (2020); and Kim et al., Applied Surface Science, 619, 156751 (2023). In one of these procedures, cobalt was etched at temperatures higher than 377° C. and exposing the cobalt surface (with a native oxide) to 1,1,1,5,5,5-hexafluoro-2,4,-pentanedione (Hhfac). The treated surface was then heated to produce sublimation of cobalt 1,1,1,5,5,5-hexafluoro-2,4,-pentanedionate. In a variant, cobalt was etched at temperatures higher than 140° C. by sequentially exposing the cobalt surface to:
(A) chlorine which oxidizes a layer of cobalt into cobalt chloride (surface activation); and
(B) an acetylacetone (such as 1,1,1,5,5,5-hexafluoro-2,4,-pentanedione (Hhfac)), which react with the cobalt chloride surface species to generate volatile cobalt chloro-acetylacetonate species (sublimation).

In another method, cobalt etching at temperatures higher than 80° C. was achieved with an etching rate was as high as 28 Å/cycle. See, e.g., Chen et al., J. Vac. Sci. Technol., A 35, 05C305 (2017). This process involved the sequential exposure of a cobalt surface to:
(A) An oxygen plasma which oxidizes multiple layers of cobalt into cobalt oxide (surface activation); and
(B) Formic acid, which react with the cobalt oxide surface species to generate volatile cobalt formate species (sublimation).

An alternative method was used to etch cobalt and copper thin films by using supercritical CO₂ and 1,1,1,5,5,5-hexafluoro-2,4,-pentanedione at 100° C. and 250° C. under high-pressure. See, e.g., Rasadujjaman et al., Microelectron. Eng. 153, 5 (2016).

A copper etching process was described in which copper was chlorinated using a plasma to generate CuCl₂. See, e.g., Tamirisa et al., Microelectron. Eng. 84, 105 (2007); Wu et al., J. Electrochem. Soc., 157, H474 (2010); and Hess D.W., Workshop on Atomic-Layer-Etch and Clean Technology, San Francisco, Ca (2014). The CuCl₂ layer was then etched with a hydrogen plasma, which generated volatile Cu₃Cl₃. This process could be performed at temperatures as low as 20° C., but its application for etching Cu in small features was limited because of significant profile taper.

Another method reported etching copper at temperatures higher than 275° C. with an etch rate of 0.09 nm/cycle. See, e.g., Mohimi et al., ECS Journal of Solid State Science and Technology, 7, P491 (2018). This process involved the sequential exposure of a copper surface to:
(A) oxygen which is a mild oxidizer and oxidizes a layer of copper into copper oxide (surface activation); and
(B) an acetylacetone (such as 1,1,1,5,5,5-hexafluoro-2,4,-pentanedione (Hhfac), which reacts with the copper oxide surface species to generate volatile copper acetylacetonate species (sublimation).

Another method involved the etching of tungsten. See, e.g., Johnson N. R. and George S. M., ACS Applied Materials & Interfaces, 9, 34435 (2017). In this process, tungsten could be etched (between 128° C. and 207° C.) by sequentially exposing a tungsten surface having a native oxide layer to:
(A) A mixture of oxygen and ozone, which oxidizes an additional layer of tungsten into tungsten oxide (surface activation);
(B) Boron trichloride, which reacts with some of the tungsten oxide to generate non-volatile boron oxide and volatile tungsten oxychloride (sublimation of tungsten-containing species; some tungsten oxide is still present below the boron oxide); and
(C) Hydrogen fluoride, which react with the boron oxide to generate volatile water vapor, and volatile boron trifluoride (regeneration of fresh tungsten oxide surface).

Some implementations of ALE include cycling the following steps in a vacuum chamber tool, such as an atomic layer deposition (ALD) reactor: (1) dosing a first chlorinating agent to convert surface Co, which is a solid, into CoCl₂, which is also a solid; (2) a first purge of the reactor; (3) dosing a second volatilizing agent to convert CoCl₂, which is a solid, into a metal-organic complex or adduct, which is a gas; and (4) a second purge of the reactor.

In contrast to some of the examples above, the disclosed methods do not require a plasma and do not require the use of corrosive halogenating gases. The disclosed methods may also use halogen-free volatilizing agents which reduce the possibility of deleterious surface contamination from the etch process.

In the disclosed and claimed subject matter, a metal-containing surface material (e.g., a thin layer of a metal compound, with the metal oxidation state greater than zero, atop a metal) is exposed to a halogen-free organic acid, such as propionic acid, isobutyric acid, or pivalic acid, in the vapor phase. The metal-containing surface material reacts with the halogen-free organic acid, forming a volatile metal-organic complex, whereas the underlying material is not affected. In a further aspect of the disclosed and claimed subject matter, doses of the halogen-free organic acid are cycled with an inert gas purge to improve control of the etch. In a further aspect of the disclosed and claimed subject matter, an atomic layer etch (ALE) process is described in which a surface modification agent, such as a chlorinator, is dosed to form a metal compound on a surface, and a halogen-free organic acid is dosed to the surface to remove the newly formed metal compound, enabling the controlled removal of the metal.

### SUMMARY

In one embodiment, the disclosed and claimed subject matter relates to a method for selective thermal vapor-phase etch processing of metal-containing materials, including metals, metal alloys, and metal compounds. The method generally includes a Volatilization Step that includes, consists essentially of or consists of (i) exposing the metal-containing material to one or more volatilizing agents to produce a volatile byproduct containing one or more metals from the metal-containing material and (ii) a purge. The Volatilization Step can be repeated as many times as desired to selectively remove a desired thickness of a metal compound.

In another embodiment, the disclosed and claimed subject matter relates to a method for selective thermal vapor-phase etch metal-containing materials, including metals, metal alloys, and metal compounds. The method includes, consists essentially of or consists of the Volatilization Step described above and a Surface Modification Step. The Surface Modification Step includes, consists essentially of or consists of (a) exposing the metal-containing material to one or more surface modification agents to form a volatilizable metal-containing material that is different than the metal-containing material prior to exposure to the one or more surface modification agents and (b) a purge.

In another embodiment, the disclosed and claimed subject matter relates to repeating steps (a), (b), (i), and (ii) as many times as desired to selectively remove a desired thickness of a metal.

In a further aspect of this embodiment, the surface modification agent contains a halogen. In a further aspect of this embodiment, the surface modification agent contains chlorine.

In another embodiment, the disclosed and claimed subject matter relates to a method for thermal vapor-phase etch processing in which one material, such as a metal, metal compound, or a set thereof, is etched, whereas another material, such as another metal, metal compound, nonmetal, nonmetal compound, or set thereof, is not etched.

In another embodiment, the disclosed and claimed subject matter relates to a method for thermal vapor-phase etch processing in which a thin layer of a metal compound is etched, whereas a metal or metal alloy is not etched. In another embodiment, the metal compound includes one or more elements of the metal or metal alloy. In another embodiment, the metal compound includes a thin film atop the metal or metal alloy.

In one aspect, the disclosed and claimed subject matter relates to processes for the thermal vapor-phase etch of metals, including Co, Ni, Cu, Mo, Ru, and W. In another aspect, the disclosed and claimed subject matter relates to processes for the thermal vapor-phase etch of metal compounds, including compounds containing Ti, Co, Ni, Cu, Mo, Ru, Ta and/or W. In another aspect, the disclosed and claimed subject matter relates to processes for the atomic layer etch (ALE) of metals, including Co, Ni, Cu, Mo, Ru, and W. In another aspect, the disclosed and claimed subject matter relates to processes for the vapor-phase etch of compounds, such as oxides, hydroxides, oxyhydroxides, carbonates, carbides, nitrides, fluorides, or chlorides of metals, including Ti, Co, Ni, Cu, Mo, Ru, Ta and/or W.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity's sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates an exemplary cycle of the disclosed and claimed processes for vapor-phase etch of a metal-containing material;

FIG. 2 illustrates an exemplary cycle of the disclosed and claimed processes for vapor-phase etch of a metal-containing material by surface modification and volatilization (i.e., ALE); and

FIG. 3 illustrates an exemplary cycle of a disclosed and claimed process for ALE of cobalt.

### DEFINITIONS

Unless otherwise stated, the following terms used in the specification and claims shall have the following meanings for this application.

For purposes of the disclosed and claimed subject matter, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal oxide film, metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds., The Royal Society of Chemistry: Cambridge, 2009; Chapter 1, pp. 1-36.

As used herein, the term “feature” refers to an opening in a substrate which may be defined by one or more sidewalls, a bottom surface, and upper corners. In various aspects, the feature may be a via, a trench, contact, dual damascene, etc.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

The volatilizing agent and surface modification agent are preferably substantially free of water. As used herein, the term “substantially free” as it relates to water, means less than 5000 ppm (by weight) measured by proton NMR or Karl Fischer titration, preferably less than 3000 ppm measured by proton NMR or Karl Fischer titration, and more preferably less than 1000 ppm measured by proton NMR or Karl Fischer titration, and most preferably less than 100 ppm measured by proton NMR or Karl Fischer titration.

Halo or halide refers to a halogen, F, Cl, Br or I which is linked by one bond to an organic or metallic moiety. In some embodiments, the halogen is F. In other embodiments, the halogen is Cl. In other embodiments, the halogen is Br. In other embodiments, the halogen is I.

Halogenated alkyl refers to a C₁ to C₂₀ alkyl which is fully or partially halogenated.

Perfluoroalkyl refers to a linear, cyclic or branched saturated alkyl group as defined above in which the hydrogens have all been replaced by fluorine (e.g., trifluoromethyl, perfluoroethyl, perfluoropropyl, perfluorobutyl, perfluoroisopropyl, perfluorocyclohexyl and the like).

The disclosed and claimed precursors are preferably substantially free of organic impurities which are from either starting materials employed during synthesis or by-products generated during synthesis. Examples include, but not limited to, alkanes, alkenes, alkynes, dienes, ethers, esters, acetates, amines, ketones, amides, aromatic compounds. As used herein, the term “free of” organic impurities, means 1000 ppm or less as measured by GC, preferably 500 ppm or less (by weight) as measured by GC, most preferably 100 ppm or less (by weight) as measured by GC or other analytical method for assay. Importantly the precursors preferably have purity of 98 wt % or higher, more preferably 99 wt % or higher as measured by GC when used as precursor to deposit the ruthenium-containing films.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

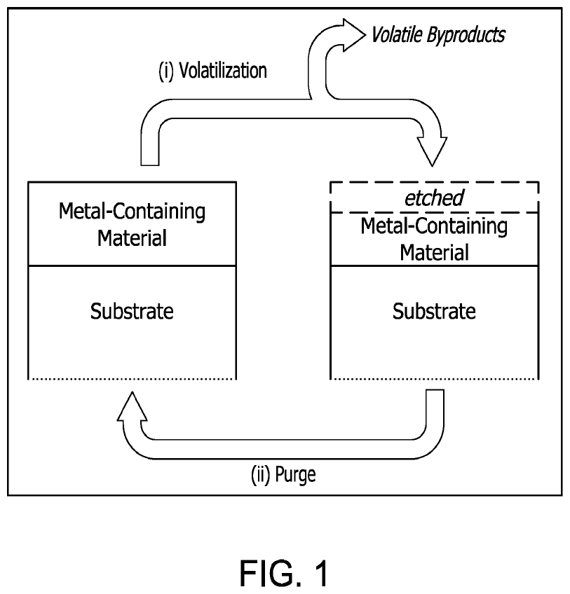

The disclosed and claimed subject matter relates to processes for selectively etching a metal-containing material from a surface of a substrate that includes, consists essentially of or consists of a Volatilization Step (illustrated schematically in FIG. 1) that includes, consists essentially of or consists of:
(i) exposing the metal-containing material to one or more volatilizing agents to produce a volatile byproduct containing one or more metals from the metal-containing material; and
(ii) a purge.

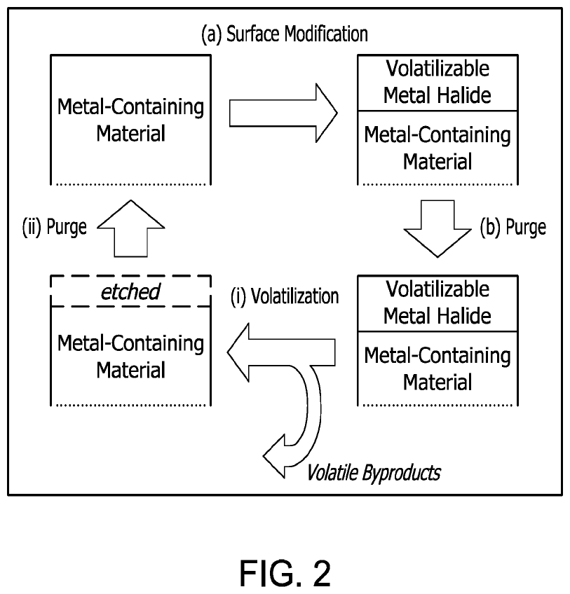

This process can optionally be coupled with a Surface Modification Step (illustrated schematically in FIG. 2) that includes, consists essentially of or consists of:
(a) exposing the metal-containing material to one or more surface modification agents to form a volatilizable metal-containing material that is different than the metal-containing material prior to exposure to the one or more surface modification agents; and
(b) a purge.

Thus, in one embodiment, illustrated schematically in FIG. 1, the disclosed and claimed subject matter relates to the Volatilization Step for the selective vapor-phase etching of metal-containing materials. These processes include, consist essentially of or consist of the steps of:
(i) exposing the metal-containing material surface to one or more volatilizing agents to produce a volatile byproduct containing one or more metals from the metal-containing material; and
(ii) a purge.

In a further aspect of this embodiment, the method consists essentially of steps (i) and (ii). In a further aspect of this embodiment, the method consists of steps (i) and (ii). The steps in the processes can be cycled as many times as needed to remove a desired thickness of metal or metal compound.

In another embodiment, an example of which is illustrated schematically in FIG. 2, the disclosed and claimed subject matter relates to processes for the selective ALE of metal-containing materials in which the process includes, consists essentially of or consists of both the Volatilization

Step and the Surface Modification Step. Thus, in this embodiment, these processes include, consist essentially of or consist of the steps of:
(a) exposing the metal-containing material to one or more surface modification agents to form a volatilizable metal-containing material that is different than the metal-containing material prior to exposure to the one or more surface modification agents; and
(b) a purge; and
(i) a volatilization including exposing the modified surface to one or more volatilizing agents to produce a volatile byproduct; and
(ii) a purge.

In a further aspect of this embodiment, the surface modification agent is a halogenator. In a further aspect of this embodiment, the surface modification agent converts the metal-containing material at the surface into a volatilizable metal halide.

In a further aspect of this embodiment, the method consists essentially of steps (a), (b), (i), and (ii). In a further aspect of this embodiment, the method consists of steps (a), (b), (i), and (ii). The steps in the processes can be cycled as many times as needed to remove a desired thickness of a metal-containing material. When the process includes, consists essentially of or consists of both the Volatilization Step and the Surface Modification Step, the Volatilization Step can precede the Surface Modification Step or the Surface Modification Step can precede the Volatilization Step.

### Number of Cycles

As noted above, in the disclosed and claimed etch processes, the steps can be cycled as many times as needed to remove a desired thickness of a metal or a metal compound. In some of the above-described embodiments, as well as some of the other embodiments described herein, the described steps define one cycle of the process. As those skilled in the art will understand (and as noted above), the disclosed and claimed processes will include purge steps between doses of vapor-phase reactants. Purge steps do not have to be performed between iterations of a single step (i.e., between multiple iterations of step (i) or between multiple iterations of step (a)).

In one embodiment, a single cycle of a vapor-phase etch process is to be understood as beginning when the first iteration of step (i) is performed and ending when the last purge step (ii) is performed before another iteration step (i) is performed again regardless of the number of purging steps conducted during the process. It is to be understood that a cycle can be repeated until the desired thickness of a film is obtained.

In another embodiment, a single cycle of an ALE etch process is to be understood as beginning when the first iteration of step (a) is performed and ending when the last purge step (ii) is performed before another iteration step (a) is performed again regardless of the number of purging steps conducted during the process. It is to be understood that a cycle can be repeated until the desired thickness of a film is obtained.

In one embodiment, the number of cycles is from about 100 to about 1000. In one embodiment, the number of cycles is from about 20 to about 250. In one embodiment, the number of cycles is from about 10 to about 150. In one embodiment, the number of cycles is from about 5 to about 100. In one embodiment, the number of cycles is from about 5 to about 75. In one embodiment, the number of cycles is from about 5 to about 50. In one embodiment, the number of cycles is from about 5 to about 30. In one embodiment, the number of cycles is from about 5 to about 20. In one embodiment, the number of cycles is from about 15 to about 400. In one embodiment, the number of cycles is from about 20 to about 300. In one embodiment, the number of cycles is from about 25 to about 250. In one embodiment, the number of cycles is from about 35 to about 200. In one embodiment, the number of cycles is from about 45 to about 170. In one embodiment, the number of cycles is from about 50 to about 150. In one embodiment, the number of cycles is from about 75 to about 125. In one embodiment, the number of cycles is from about 25 to about 100. In one embodiment, the number of cycles is from about 50 to about 100. In one embodiment, the number of cycles is from about 75 to about 100.

In one embodiment, the number of cycles is about 5. In one embodiment, the number of cycles is about 10. In one embodiment, the number of cycles is about 15. In one embodiment, the number of cycles is about 20. In one embodiment, the number of cycles is about 25. In one embodiment, the number of cycles is about 30. In one embodiment, the number of cycles is about 35. In one embodiment, the number of cycles is about 40. In one embodiment, the number of cycles is about 45. In one embodiment, the number of cycles is about 50. In one embodiment, the number of cycles is about 75. In one embodiment, the number of cycles is about 100. In one embodiment, the number of cycles is about 125. In one embodiment, the number of cycles is about 150. In one embodiment, the number of cycles is about 175. In one embodiment, the number of cycles is about 200. In one embodiment, the number of cycles is about 225. In one embodiment, the number of cycles is about 250. In one embodiment, the number of cycles is about 275. In one embodiment, the number of cycles is about 300. In one embodiment, the number of cycles is about 325. In one embodiment, the number of cycles is about 350. In one embodiment, the number of cycles is about 400. In one embodiment, the number of cycles is about 450. In one embodiment, the number of cycles is about 500. In one embodiment, the number of cycles is about 750. In one embodiment, the number of cycles is about 1000.

The Volatilization Step and the Surface Modification Step of the disclosed and claimed etch processes are described in more detail as follows. The steps are listed in order of their implementation in an embodiment of an ALE process in which the Surface Modification Step precedes the Volatilization Step.

### Surface Modification Step

### Step (a)

In the step (a), metal-containing material on a surface of a substrate is exposed to one or more surface modification agents to convert the metal-containing material into a corresponding metal halide species and thereby producing a metal halide surface which can be volatilized, as shown in FIG. 2. Having been thus converted, the surface metal halide can then be converted to a volatile species (e.g., through the Volatilization Step described below) so that some or all of the metal-containing material on the surface of the substrate can be removed.

### Metal-Containing Material

The metal-containing material includes any acceptable and/or desirable metal, metal alloy, or metal compound. In one embodiment, the metal-containing material includes one or more of Co, Ni, Cu, Mo, Ru, W, TiN, or TaN. In one aspect of this embodiment, the metal-containing material includes Co. In one aspect of this embodiment, the metal-containing material includes Ni. In one aspect of this embodiment, the metal-containing material includes Cu. In one aspect of this embodiment, the metal-containing material includes Mo. In one aspect of this embodiment, the metal-containing material includes Ru. In one aspect of this embodiment, the metal-containing material includes W. In one aspect of this embodiment, the metal-containing material includes TiN. In one aspect of this embodiment, the metal-containing material includes TaN.

### Surface Modification Agents

In some embodiments, the surface modification agent includes, consists essentially of or consists of one or more halogenating agents (i.e., a halogenator).

In preferred embodiments, the surface modification agent includes, consists essentially of or consists of one or more chlorinating agents. In one embodiment, the surface modification agent includes, consists essentially of or consists of one or more of SOCl₂, Cl₂, BCl₃, HCl, or TiCl₄. In one aspect of this embodiment, the surface modification agent includes SOCl₂. In one aspect of this embodiment, the surface modification agent includes Cl₂. In one aspect of this embodiment, the surface modification agent includes BCl₃. In one aspect of this embodiment, the surface modification agent includes HCl. In one aspect of this embodiment, the surface modification agent includes TiCl₄.

In another embodiment, the surface modification agent includes, consists essentially of or consists of one or more brominating agents. In one embodiment, the surface modification agent includes, consists essentially of or consists of one or more of SOBr₂, Br₂, BBr₃, HBr, or TiBr₄. In one aspect of this embodiment, the surface modification agent includes SOBr₂. In one aspect of this embodiment, the surface modification agent includes Br₂. In one aspect of this embodiment, the surface modification agent includes BBr₃. In one aspect of this embodiment, the surface modification agent includes HBr. In one aspect of this embodiment, the surface modification agent includes TiBr₄.

In another embodiment, the surface modification agent includes, consists essentially of or consists of one or more iodinating agents. In one embodiment, the surface modification agent includes, consists essentially of or consists of one or more of I₂, BI₃, HI, or TiI₄. In one aspect of this embodiment, the surface modification agent includes I₂. In one aspect of this embodiment, the surface modification agent includes BI₃. In one aspect of this embodiment, the surface modification agent includes HI. In one aspect of this embodiment, the surface modification agent includes TiI₄.

### Conditions

### Time

As noted above, in step (a), the one or more metals or metal compounds is exposed to the surface modification agent for a period of time (“exposure time”) before moving to step (b), resulting in formation of a thin metal halide at the surface. In one embodiment, the step (a) surface modification agent exposure time is from about 0.5 seconds to about 30 seconds. In one embodiment, the step (a) surface modification agent exposure time is from about 0.5 seconds to about 10 seconds. In one embodiment, the step (a) surface modification agent exposure time is from about 1 second to about 7 seconds. In one embodiment, the step (a) surface modification agent exposure time is from about 7 seconds to about 10 seconds. In one embodiment, the step (a) surface modification agent exposure time is from about 10 seconds to about 20 seconds. In one embodiment, the step (a) surface modification agent exposure time is from about 20 seconds to about 30 seconds. In one embodiment, the step (a) surface modification agent exposure time is about 0.25 seconds. In one embodiment, the step (a) surface modification agent exposure time is about 0.5 seconds. In one embodiment, the step (a) surface modification agent exposure time is about 1 second. In one embodiment, the step (a) surface modification agent exposure time is about 2 seconds. In one embodiment, the step (a) surface modification agent exposure time is about 3 seconds. In one embodiment, the step (a) surface modification agent exposure time is about 4 seconds. In one embodiment, the step (a) surface modification agent exposure time is about 5 seconds. In one embodiment, the step (a) surface modification agent exposure time is about 6 seconds. In one embodiment, the step (a) surface modification agent exposure time is about 7 seconds. In one embodiment, the step (a) surface modification agent exposure time is about 8 seconds. In one embodiment, the step (a) surface modification agent exposure time is about 9 seconds. In one embodiment, the step (a) surface modification agent exposure time is about 10 seconds. In one embodiment, the step (a) surface modification agent exposure time is about 12 seconds. In one embodiment, the step (a) surface modification agent exposure time exposure is about 15 seconds. In one embodiment, the step (a) surface modification agent exposure time is about 17 seconds. In one embodiment, the step (a) surface modification agent exposure time is about 20 seconds. In one embodiment, the step (a) surface modification agent exposure time is about 25 seconds. In one embodiment, the step (a) surface modification agent exposure time is about 30 seconds.

### Dosing of Surface Modification Agent

In one embodiment, the surface modification agent is flowed at from about 5 sccm to about 500 sccm. In one embodiment, the surface modification agent is flowed at from about 0.5 sccm to about 100 sccm. In one embodiment, the surface modification agent is flowed at from about 1 sccm to about 200 sccm. In one embodiment, the surface modification agent is flowed at from about 1 sccm to about 100 sccm. In one embodiment, the surface modification agent is flowed at from about 1 sccm to about 50 sccm. In one embodiment, the surface modification agent is flowed at from about 5 sccm to about 25 sccm. In one embodiment, the surface modification agent is flowed at from about 10 sccm to about 20 sccm. In one embodiment, the surface modification agent is flowed at from about 15 sccm to about 25 sccm. In one embodiment, the surface modification agent is flowed at about 5 sccm. In one embodiment, the surface modification agent is flowed at about 10 sccm. In one embodiment, the surface modification agent is flowed at about 15 sccm. In one embodiment, the surface modification agent is flowed at about 20 sccm. In one embodiment, the surface modification agent is flowed at about 25 sccm. In one embodiment, the surface modification agent is flowed at about 30 sccm. In one embodiment, the surface modification agent is flowed at about 35 sccm. In one embodiment, the surface modification agent is flowed at about 40 sccm. In one embodiment, the surface modification agent is flowed at about 45 sccm. In one embodiment, the surface modification agent is flowed at about 50 sccm. In one embodiment, the surface modification agent is flowed at about 60 sccm. In one embodiment, the surface modification agent is flowed at about 70 sccm. In one embodiment, the surface modification agent is flowed at about 80 sccm. In one embodiment, the surface modification agent is flowed at about 90 sccm. In one embodiment, the surface modification agent is flowed at about 100 sccm. In one embodiment, the surface modification agent is flowed at about 125 sccm. In one embodiment, the surface modification agent is flowed at about 150 sccm. In one embodiment, the surface modification agent is flowed at about 200 sccm. In one embodiment, the surface modification agent is flowed at about 250 sccm. In one embodiment, the surface modification agent is flowed at about 300 sccm. In one embodiment, the surface modification agent is flowed at about 350 sccm. In one embodiment, the surface modification agent is flowed at about 400 sccm. In one embodiment, the surface modification agent is flowed at about 450 sccm. In one embodiment, the surface modification agent is flowed at about 500 sccm.

In one embodiment, the surface modification agent is supplied alone.

In one embodiment, the surface modification agent is supplied with a suitable carrier gas. In one embodiment, the carrier gas includes argon. In one embodiment, the carrier gas includes nitrogen.

In one embodiment, the surface modification agent is supplied by vapor draw.

In one embodiment, the surface modification agent is dosed as a component of a plasma. In one embodiment, the surface modification agent is dosed as a plasma.

### Pressure

The step (a) surface modification can be carried out at any suitable chamber pressure. In one embodiment, the pressure is from about 0.05 torr to about 10 torr. In one embodiment, the pressure is from about 0.5 torr to about 100 torr. In one embodiment, the pressure is from about 0.5 torr to about 15 torr. In one embodiment, the pressure is from about 1 torr to about 10 torr. In one embodiment, the pressure is from about 1 torr to about 5 torr. In one embodiment, the pressure is from about 0.2 torr to about 2 torr. In one embodiment, the pressure is about 0.05 torr. In one embodiment, the pressure is about 0.1 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr. In one embodiment, the pressure is about 10 torr. In one embodiment, the pressure is about 15 torr. In one embodiment, the pressure is about 20 torr. In one embodiment, the pressure is about 25 torr. In one embodiment, the pressure is about 30 torr. In one embodiment, the pressure is about 40 torr. In one embodiment, the pressure is about 50 torr. In one embodiment, the pressure is about 60 torr. In one embodiment, the pressure is about 75 torr. In one embodiment, the pressure is about 100 torr.

### Exemplary Step (a)

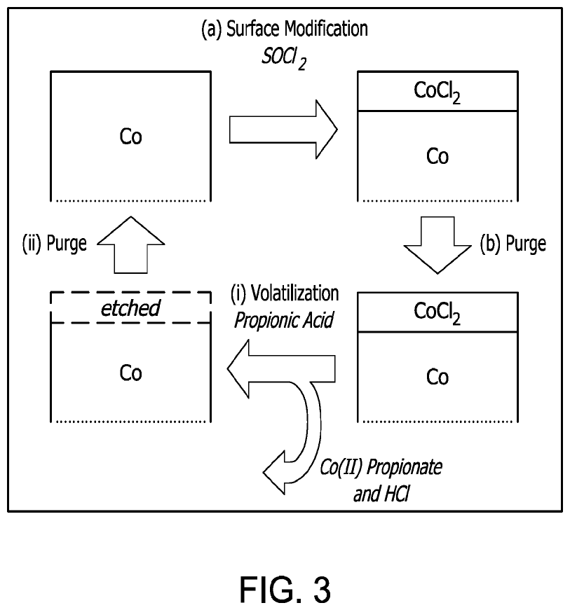

In an exemplary embodiment of the step (a) chlorination, and as illustrated in FIG. 3, a Co surface is exposed to thionyl chloride (SOCl₂), thereby converting the solid Co to solid CoCl₂ along with the release of volatile O, S, and/or Cl compounds.

### Step (b)

In the step (b), any suitable inert purge gas can be used. In one embodiment, the purge gas includes argon. In one embodiment, the purge gas includes nitrogen.

### Time

In one embodiment, the step (b) purge time is from about 0.5 seconds to about 30 seconds. In one embodiment, the step (b) purge time is from about 0.25 seconds to about 10 seconds. In one embodiment, the step (b) purge time is from about 1 second to about 7 seconds. In one embodiment, the step (b) purge time is from about 7 seconds to about 10 seconds. In one embodiment, the step (b) purge time is from about 10 seconds to about 20 seconds. In one embodiment, the step (b) purge time is from about 20 seconds to about 30 seconds. In one embodiment, the step (b) purge time is from about 30 seconds to about 60 seconds. In one embodiment, the step (b) purge time is about 0.25 seconds. In one embodiment, the step (b) purge time is about 0.5 seconds. In one embodiment, the step (b) purge time is about 1 second. In one embodiment, the step (b) purge time is about 2 seconds. In one embodiment, the step (b) purge time is about 3 seconds. In one embodiment, the step (b) purge time is about 4 seconds. In one embodiment, the step (b) purge time is about 5 seconds. In one embodiment, the step (b) purge time is about 6 seconds. In one embodiment, the step (b) purge time is about 7 seconds. In one embodiment, the step (b) purge time is about 8 seconds. In one embodiment, the step (b) purge time is about 9 seconds. In one embodiment, the step (b) purge time is about 10 seconds. In one embodiment, the step (b) purge time is about 12 seconds. In one embodiment, the step (b) purge time exposure is about 15 seconds. In one embodiment, the step (b) purge time is about 17 seconds. In one embodiment, the step (b) purge time is about 20 seconds. In one embodiment, the step (b) purge time is about 25 seconds. In one embodiment, the step (b) purge time is about 30 seconds. In one embodiment, the step (b) purge time is about 35 seconds. In one embodiment, the step (b) purge time is about 40 seconds. In one embodiment, the step (b) purge time is about 50 seconds. In one embodiment, the step (b) purge time is about 60 seconds.

### Flow Rate

In one embodiment, the purge gas is flowed at from about 100 sccm to about 5000 sccm. In one embodiment, the purge gas is flowed at from about 500 sccm to about 2500 sccm. In one embodiment, the purge gas is flowed at from about 1000 sccm to about 2000 sccm. In one embodiment, the purge gas is flowed at about 100 sccm. In one embodiment, the purge gas is flowed at about 200 sccm. In one embodiment, the purge gas is flowed at about 300 sccm. In one embodiment, the purge gas is flowed at about 400 sccm. In one embodiment, the purge gas is flowed at about 500 sccm. In one embodiment, the purge gas is flowed at about 1000 sccm. In one embodiment, the purge gas is flowed at about 1500 sccm. In one embodiment, the purge gas is flowed at about 2000 sccm. In one embodiment, the purge gas is flowed at about 2500 sccm. In one embodiment, the purge gas is flowed at about 3000 sccm. In one embodiment, the purge gas is flowed at about 3500 sccm. In one embodiment, the purge gas is flowed at about 4000 sccm. In one embodiment, the purge gas is flowed at about 4500 sccm. In one embodiment, the purge gas is flowed at about 5000 sccm.

### Pressure

The step (b) purge step can be carried out at any suitable chamber pressure. In one embodiment, the pressure is from about 0.05 torr to about 10 torr. In one embodiment, the pressure is from about 0.5 torr to about 100 torr. In one embodiment, the pressure is from about 0.5 torr to about 15 torr. In one embodiment, the pressure is from about 1 torr to about 10 torr. In one embodiment, the pressure is from about 1 torr to about 5 torr. In one embodiment, the pressure is from about 0.2 torr to about 2 torr. In one embodiment, the pressure is about 0.05 torr. In one embodiment, the pressure is about 0.1 torr. In one embodiment, the pressure is about 0.2 torr. In one embodiment, the Pressure pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr. In one embodiment, the pressure is about 10 torr. In one embodiment, the pressure is about 15 torr. In one embodiment, the pressure is about 20 torr. In one embodiment, the pressure is about 25 torr. In one embodiment, the pressure is about 30 torr. In one embodiment, the pressure is about 40 torr. In one embodiment, the pressure is about 50 torr. In one embodiment, the pressure is about 60 torr. In one embodiment, the pressure is about 75 torr. In one embodiment, the pressure is about 100 torr.

### Volatilization Step

### Step (i)

In the step (i), the metal-containing material on a surface of a substrate is exposed to one or more volatilizing agents for a period of time sufficient to produce a volatile byproduct (i.e., a volatile metal-containing species) due to the reaction between the one or more volatilizing agents and the metal-containing material. As a result of being converted to a volatile product some or all of the metal-containing material on the surface of the substrate can be removed. See FIG. 1.

### Volatilizing Agents

The volatilizing agent includes, consists essentially of, or consists of one or more compounds that provide one or more ligands capable of forming coordination complexes with the metal-containing material or a chlorinated metal surface thereof. In one embodiment, the volatilizing agent includes, consists essentially of, or consists of a halogen-free organic acid or mixture of halogen-free organic acids.

In one embodiment, the one or more volatilizing agent includes one or more of propionic acid, isobutyric acid, pivalic acid, acetic acid, butanoic acid, acrylic acid, methacrylic acid, 2-methylbutanoic acid, 3-methylbutanoic acid, 3-butenoic acid, cyclopropanecarboxylic acid, pentanoic acid, (2E)-but-2-enoic acid, (Z)-2-butenoic acid and combinations thereof. In one embodiment, the one or more volatilizing agent includes one or more of propionic acid, isobutyric acid, pivalic acid, acetic acid, butanoic acid, acrylic acid, methacrylic acid, 2-methylbutanoic acid, 3-methylbutanoic acid, 3-butenoic acid and combinations thereof. In one embodiment, the one or more volatilizing agent includes one or more of propionic acid, isobutyric acid, pivalic acid, acetic acid, butanoic acid and combinations thereof. In one embodiment, the one or more volatilizing agent includes one or more of propionic acid, isobutyric acid, pivalic acid and combinations thereof. In one aspect of this embodiment, the one or more volatilizing agent includes propionic acid. In one aspect of this embodiment, the one or more volatilizing agent includes isobutyric acid. In one aspect of this embodiment, the one or more volatilizing agent includes pivalic acid. In one aspect of this embodiment, the one or more volatilizing agent includes acetic acid. In one aspect of this embodiment, the one or more volatilizing agent includes butanoic acid. In one aspect of this embodiment, the one or more volatilizing agent includes acrylic acid. In one aspect of this embodiment, the one or more volatilizing agent includes methacrylic acid. In one aspect of this embodiment, the one or more volatilizing agent includes 2-methylbutanoic acid. In one aspect of this embodiment, the one or more volatilizing agent includes 3-methylbutanoic acid. In one aspect of this embodiment, the one or more volatilizing agent includes 3-butenoic acid. In one aspect of this embodiment, the one or more volatilizing agent includes cyclopropanecarboxylic acid. In one aspect of this embodiment, the one or more volatilizing agent includes pentanoic acid. In one aspect of this embodiment, the one or more volatilizing agent includes (2E)-but-2-enoic acid. In one aspect of this embodiment, the one or more volatilizing agent includes (Z)-2-butenoic acid. In one aspect of this embodiment, the one or more volatilizing agent includes a mixture of one or more of propionic acid, isobutyric acid and pivalic acid. In one aspect of this embodiment, the one or more volatilizing agent includes a mixture of two or more of propionic acid, isobutyric acid and pivalic acid. In one aspect of this embodiment, the one or more volatilizing agent includes a mixture of halogen-free organic acids including one or more of propionic acid, isobutyric acid and pivalic acid.

### Conditions

### Time

In one embodiment, the step (i) volatilization time is from about 0.5 seconds to about 30 seconds. In one embodiment, the step (i) volatilization time is from about 0.5 seconds to about 10 seconds. In one embodiment, the step (i) volatilization time is from about 1 second to about 7 seconds. In one embodiment, the step (i) volatilization time is from about 7 seconds to about 10 seconds. In one embodiment, the step (i) volatilization time is from about 10 seconds to about 20 seconds. In one embodiment, the step (i) volatilization time is from about 20 seconds to about 30 seconds. In one embodiment, the step (i) volatilization time is about 0.25 seconds. In one embodiment, the step (i) volatilization time is about 0.5 seconds. In one embodiment, the step (i) volatilization time is about 1 second. In one embodiment, the step (i) volatilization time is about 2 seconds. In one embodiment, the step (i) volatilization time is about 3 seconds. In one embodiment, the step (i) volatilization time is about 4 seconds. In one embodiment, the step (i) volatilization time is about 5 seconds. In one embodiment, the step (i) volatilization time is about 6 seconds. In one embodiment, the step (i) volatilization time is about 7 seconds. In one embodiment, the step (i) volatilization time is about 8 seconds. In one embodiment, the step (i) volatilization time is about 9 seconds. In one embodiment, the step (i) volatilization time is about 10 seconds. In one embodiment, the step (i) volatilization time is about 12 seconds. In one embodiment, the step (i) volatilization time exposure is about 15 seconds. In one embodiment, the step (i) volatilization time is about 17 seconds. In one embodiment, the step (i) volatilization time is about 20 seconds. In one embodiment, the step (i) volatilization time is about 25 seconds. In one embodiment, the step (i) volatilization time is about 30 seconds.

### Flow Rate of Volatilizing Agent

In one embodiment, the volatilizing agent is flowed at from about 1 sccm to about 500 sccm. In one embodiment, the volatilizing agent is flowed at from about 5 sccm to about 500 sccm. In one embodiment, the volatilizing agent is flowed at from about 0.5 sccm to about 100 sccm. In one embodiment, the volatilizing agent is flowed at from about 1 sccm to about 50 sccm. In one embodiment, the volatilizing agent is flowed at from about 5 sccm to about 25 sccm. In one embodiment, the volatilizing agent is flowed at from about 10 sccm to about 20 sccm. In one embodiment, the volatilizing agent is flowed at from about 15 sccm to about 25 sccm. In one embodiment, the volatilizing agent is flowed at about 5 sccm. In one embodiment, the volatilizing agent is flowed at about 10 sccm. In one embodiment, the volatilizing agent is flowed at about 15 sccm. In one embodiment, the volatilizing agent is flowed at about 20 sccm. In one embodiment, the volatilizing agent is flowed at about 25 sccm. In one embodiment, the volatilizing agent is flowed at about 30 sccm. In one embodiment, the volatilizing agent is flowed at about 35 sccm. In one embodiment, the volatilizing agent is flowed at about 40 sccm. In one embodiment, the volatilizing agent is flowed at about 45 sccm. In one embodiment, the volatilizing agent is flowed at about 50 sccm. In one embodiment, the volatilizing agent is flowed at about 60 sccm. In one embodiment, the volatilizing agent is flowed at about 70 sccm. In one embodiment, the volatilizing agent is flowed at about 80 sccm. In one embodiment, the volatilizing agent is flowed at about 90 sccm. In one embodiment, the volatilizing agent is flowed at about 100 sccm. In one embodiment, the volatilizing agent is flowed at about 125 sccm. In one embodiment, the volatilizing agent is flowed at about 150 sccm. In one embodiment, the volatilizing agent is flowed at about 200 sccm. In one embodiment, the volatilizing agent is flowed at about 250 sccm. In one embodiment, the volatilizing agent is flowed at about 300 sccm. In one embodiment, the volatilizing agent is flowed at about 350 sccm. In one embodiment, the volatilizing agent is flowed at about 400 sccm. In one embodiment, the volatilizing agent is flowed at about 450 sccm. In one embodiment, the volatilizing agent is flowed at about 500 sccm.

In one embodiment, the volatilizing agent is supplied alone.

In one embodiment, the volatilizing agent is supplied with a suitable carrier gas. In one embodiment, the carrier gas includes argon. In one embodiment, the carrier gas includes nitrogen.

In one embodiment, the volatilizing agent is supplied by vapor draw.

### Pressure

In one embodiment, the pressure is from about 0.05 torr to about 10 torr. In one embodiment, the pressure is from about 0.5 torr to about 100 torr. In one embodiment, the pressure is from about 0.5 torr to about 15 torr. In one embodiment, the pressure is from about 1 torr to about 10 torr. In one embodiment, the pressure is from about 1 torr to about 5 torr. In one embodiment, the pressure is from about 0.2 torr to about 2 torr. In one embodiment, the pressure is about 0.05 torr. In one embodiment, the pressure is about 0.1 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr. In one embodiment, the pressure is about 10 torr. In one embodiment, the pressure is about 15 torr. In one embodiment, the pressure is about 20 torr. In one embodiment, the pressure is about 25 torr. In one embodiment, the pressure is about 30 torr. In one embodiment, the pressure is about 40 torr. In one embodiment, the pressure is about 50 torr. In one embodiment, the pressure is about 60 torr. In one embodiment, the pressure is about 75 torr. In one embodiment, the pressure is about 100 torr.

### Exemplary Step (i)

In an exemplary embodiment of the step (i) volatilization, and as illustrated in FIG. 3, a layer of CoCl₂ atop the surface of Co (as described above) undergoes ligand exchange with propionic acid to form volatile cobalt (II) propionate and volatile HCl.

### Step (ii)

In the step (ii) purge, any suitable inert purge gas can be used. In one embodiment, the purge gas includes argon. In one embodiment, the purge gas includes nitrogen.

### Time

In one embodiment, the step (ii) purge time is from about 0.5 seconds to about 30 seconds. In one embodiment, the step (ii) purge time is from about 0.25 seconds to about 10 seconds. In one embodiment, the step (ii) purge time is from about 1 second to about 7 seconds. In one embodiment, the step (ii) purge time is from about 7 seconds to about 10 seconds. In one embodiment, the step (ii) purge time is from about 10 seconds to about 20 seconds. In one embodiment, the step (ii) purge time is from about 20 seconds to about 30 seconds. In one embodiment, the step (ii) purge time is from about 30 seconds to about 60 seconds. In one embodiment, the step (ii) purge time is about 0.25 seconds. In one embodiment, the step (ii) purge time is about 0.5 seconds. In one embodiment, the step (ii) purge time is about 1 second. In one embodiment, the step (ii) purge time is about 2 seconds. In one embodiment, the step (ii) purge time is about 3 seconds. In one embodiment, the step (ii) purge time is about 4 seconds. In one embodiment, the step (ii) purge time is about 5 seconds. In one embodiment, the step (ii) purge time is about 6 seconds. In one embodiment, the step (ii) purge time is about 7 seconds. In one embodiment, the step (ii) purge time is about 8 seconds. In one embodiment, the step (ii) purge time is about 9 seconds. In one embodiment, the step (ii) purge time is about 10 seconds. In one embodiment, the step (ii) purge time is about 12 seconds. In one embodiment, the step (ii) purge time exposure is about 15 seconds. In one embodiment, the step (ii) purge time is about 17 seconds. In one embodiment, the step (ii) purge time is about 20 seconds. In one embodiment, the step (ii) purge time is about 25 seconds. In one embodiment, the step (ii) purge time is about 30 seconds. In one embodiment, the step (ii) purge time is about 35 seconds. In one embodiment, the step (ii) purge time is about 40 seconds. In one embodiment, the step (ii) purge time is about 50 seconds. In one embodiment, the step (ii) purge time is about 60 seconds.

### Flow Rate

In one embodiment, the purge gas is flowed at from about 100 sccm to about 5000 sccm. In one embodiment, the purge gas is flowed at from about 500 sccm to about 2500 sccm. In one embodiment, the purge gas is flowed at from about 1000 sccm to about 2000 sccm. In one embodiment, the purge gas is flowed at about 100 sccm. In one embodiment, the purge gas is flowed at about 200 sccm. In one embodiment, the purge gas is flowed at about 300 sccm. In one embodiment, the purge gas is flowed at about 400 sccm. In one embodiment, the purge gas is flowed at about 500 sccm. In one embodiment, the purge gas is flowed at about 1000 sccm. In one embodiment, the purge gas is flowed at about 1500 sccm. In one embodiment, the purge gas is flowed at about 2000 sccm. In one embodiment, the purge gas is flowed at about 2500 sccm. In one embodiment, the purge gas is flowed at about 3000 sccm. In one embodiment, the purge gas is flowed at about 3500 sccm. In one embodiment, the purge gas is flowed at about 4000 sccm. In one embodiment, the purge gas is flowed at about 4500 sccm. In one embodiment, the purge gas is flowed at about 5000 sccm.

### Pressure

The step (ii) purge step can be carried out at any suitable chamber pressure. In one embodiment, the pressure is from about 0.05 torr to about 10 torr. In one embodiment, the pressure is from about 0.5 torr to about 100 torr. In one embodiment, the pressure is from about 0.5 torr to about 15 torr. In one embodiment, the pressure is from about 1 torr to about 10 torr. In one embodiment, the pressure is from about 1 torr to about 5 torr. In one embodiment, the pressure is from about 0.2 torr to about 2 torr. In one embodiment, the pressure is about 0.05 torr. In one embodiment, the pressure is about 0.1 torr. In one embodiment, the pressure is about 0.2 torr. In one embodiment, the pressure is about 0.5 torr. In one embodiment, the pressure is about 1 torr. In one embodiment, the pressure is about 1.5 torr. In one embodiment, the pressure is about 2 torr. In one embodiment, the pressure is about 2.5 torr. In one embodiment, the pressure is about 5 torr. In one embodiment, the pressure is about 10 torr. In one embodiment, the pressure is about 15 torr. In one embodiment, the pressure is about 20 torr. In one embodiment, the pressure is about 25 torr. In one embodiment, the pressure is about 30 torr. In one embodiment, the pressure is about 40 torr. In one embodiment, the pressure is about 50 torr. In one embodiment, the pressure is about 60 torr. In one embodiment, the pressure is about 75 torr. In one embodiment, the pressure is about 100 torr.

### Chamber (Reactor) Temperatures

### Lid Heater (i.e., Process Chamber Gas Delivery Zone)

In one embodiment, the chamber lid heater is set from about 100° C. to about 200° C. In one embodiment, the chamber lid heater is set at about 100° C. In one embodiment, the chamber lid heater is set at about 130° C. In one embodiment, the chamber lid heater is set at about 150° C. In one embodiment, the chamber lid heater is set at about 200° C.

### Inner Heater (i.e., Process Chamber or Sample Pedestal)

In one embodiment, the chamber inner heater is set at from about 100° C. to about 400° C. In one embodiment, the chamber inner heater is set at about 100° C. In one embodiment, the chamber inner heater is set at about 150° C. In one embodiment, the chamber inner heater is set at about 160° C. In one embodiment, the chamber inner heater is set at about 175° C. In one embodiment, the chamber inner heater is set at about 200° C. In one embodiment, the chamber inner heater is set at about 250° C. In one embodiment, the chamber inner heater is set at about 275° C. In one embodiment, the chamber inner heater is set at about 300° C. In one embodiment, the chamber inner heater is set to about 325° C. In one embodiment, the chamber inner heater is set at about 350° C. In one embodiment, the chamber inner heater is set at about 400° C.

### Film Properties

The disclosed and claimed subject matter further includes films prepared by the methods described herein.

### Film Aspect Ratio

In one embodiment, the films etched by the methods described herein have trenches, vias or other topographical features with an aspect ratio of about 0 to about 60. In a further aspect of this embodiment, the aspect ratio is about 0 to about 0.5. In a further aspect of this embodiment, the aspect ratio is about 0.5 to about 1. In a further aspect of this embodiment, the aspect ratio is about 1 to about 50. In a further aspect of this embodiment, the aspect ratio is about 1 to about 40. In a further aspect of this embodiment, the aspect ratio is about 1 to about 30. In a further aspect of this embodiment, the aspect ratio is about 1 to about 20. In a further aspect of this embodiment, the aspect ratio is about 1 to about 10. In a further aspect of this embodiment, the aspect ratio is about 0.1. In a further aspect of this embodiment, the aspect ratio is about 0.2. In a further aspect of this embodiment, the aspect ratio is about 0.3. In a further aspect of this embodiment, the aspect ratio is about 0.4. In a further aspect of this embodiment, the aspect ratio is about 0.5. In a further aspect of this embodiment, the aspect ratio is about 0.6. In a further aspect of this embodiment, the aspect ratio is about 0.8. In a further aspect of this embodiment, the aspect ratio is about 1. In a further aspect of this embodiment, the aspect ratio is greater than about 1. In a further aspect of this embodiment, the aspect ratio is greater than about 2. In a further aspect of this embodiment, the aspect ratio is greater than about 5. In a further aspect of this embodiment, the aspect ratio is greater than about 10. In a further aspect of this embodiment, the aspect ratio is greater than about 15. In a further aspect of this embodiment, the aspect ratio is greater than about 20. In a further aspect of this embodiment, the aspect ratio is greater than about 30. In a further aspect of this embodiment, the aspect ratio is greater than about 40. In a further aspect of this embodiment, the aspect ratio is greater than about 50. In a further aspect of the forgoing embodiments and aspects thereof, the metal includes cobalt, nickel, molybdenum, ruthenium, and tungsten. In a further aspect of the forgoing embodiments and aspects thereof, the metal includes cobalt. In a further aspect of the forgoing embodiments and aspects thereof, the metal includes nickel. In a further aspect of the forgoing embodiments and aspects thereof, the metal includes molybdenum. In a further aspect of the forgoing embodiments and aspects thereof, the metal includes ruthenium. In a further aspect of the forgoing embodiments and aspects thereof, the metal includes tungsten.

### Resistivity

In another embodiment, the films etched by the methods described herein have a resistivity of between about 1 μΩ·cm to about 250 μΩ·cm. In a further aspect of this embodiment, the films have a resistivity of about 1 μΩ·cm to about 5 μΩ·cm. In a further aspect of this embodiment, the films have a resistivity of about 3 μΩ·cm to about 4 μ·cm. In a further aspect of this embodiment, the films have a resistivity of about 5μΩ·cm to about 10 μΩ·cm. In a further aspect of this embodiment, the films have a resistivity of about 10 μΩ·cm to about 50 μΩ·cm. In a further aspect of this embodiment, the films have a resistivity of about 10μΩ·cm to about 25μΩ·cm. In a further aspect of this embodiment, the films have a resistivity of about 15 μΩ·cm to about 25 μΩ·cm. In a further aspect of this embodiment, the films have a resistivity of about 25 μΩ·cm to about 35 μΩ·cm. In a further aspect of this embodiment, the films have a resistivity of about 50 μΩ·cm to about 100 μΩ·cm. In a further aspect of this embodiment, the films have a resistivity of about 100μΩ·cm to about 250μΩ·cm. In a further aspect of this embodiment, the films have a resistivity of about 1 μΩ·cm. In a further aspect of this embodiment, the films have a resistivity of about 2 μΩ·cm. In a further aspect of this embodiment, the films have a resistivity of about 3 μΩ·cm. In a further aspect of this embodiment, the films have a resistivity of about 4 μΩ·cm. In a further aspect of this embodiment, the films have a resistivity of about 5 μΩ·cm. In a further aspect of this embodiment, the films have a resistivity of about 7.5 μΩ·cm. In a further aspect of this embodiment, the films have a resistivity of about 10 μΩ·cm. In a further aspect of this embodiment, the films have a resistivity of about 15 μΩ·cm. In a further aspect of this embodiment, the films have a resistivity of about 20 μΩ·cm. In a further aspect of this embodiment, the films have a resistivity of about 25 μΩ·cm. In a further aspect of this embodiment, the films have a resistivity of about 30 μΩ·cm. In a further aspect of this embodiment, the films have a resistivity of about 35 μΩ·cm. In a further aspect of this embodiment, the films have a resistivity of about 40 μΩ·cm. In a further aspect of this embodiment, the films have a resistivity of about 50 μΩ·cm. In a further aspect of this embodiment, the films have a resistivity of about 60 μΩ·cm. In a further aspect of this embodiment, the films have a resistivity of about 80 μΩ·cm. In a further aspect of this embodiment, the films have a resistivity of about 100 μΩ·cm. In a further aspect of this embodiment, the films have a resistivity of about 150 μΩ·cm. In a further aspect of this embodiment, the films have a resistivity of about 200 μΩ·cm. In a further aspect of this embodiment, the films have a resistivity of about 250 μΩ·cm.

In a further aspect of this embodiment, the films have a resistivity of about 2 μΩ·cm to about 4 μΩ·cm. In a further aspect of this embodiment, the films have a resistivity of about 3 μΩ·cm to about 4 μΩ·cm. In a further aspect of this embodiment, the films have a resistivity of about 1 μΩ·cm to about 5 μΩ·cm. In a further aspect of this embodiment, the films have a resistivity of about 5 μΩ·cm to about 10 μΩ·cm. In a further aspect of this embodiment, the films have a resistivity of about 15μΩ·cm to about 25 μΩ·cm. In a further aspect of this embodiment, the films have a resistivity of about 20 μΩ·cm to about 30μΩ·cm. In a further aspect of this embodiment, the films have a resistivity of about 25μΩ·cm to about 35μΩ·cm.

### Substrate Surface (i.e., Metal-Containing Material Surface)

In a further aspect of the forgoing embodiments and aspects thereof, the metal-containing material includes titanium, cobalt, nickel, copper, molybdenum, ruthenium, tantalum, or tungsten. In a further aspect of the forgoing embodiments and aspects thereof, the metal-containing material includes titanium. In a further aspect of the forgoing embodiments and aspects thereof, the metal-containing material includes cobalt. In a further aspect of the forgoing embodiments and aspects thereof, the metal-containing material includes nickel. In a further aspect of the forgoing embodiments and aspects thereof, the metal-containing material includes copper. In a further aspect of the forgoing embodiments and aspects thereof, the metal-containing material includes molybdenum. In a further aspect of the forgoing embodiments and aspects thereof, the metal-containing material includes ruthenium. In a further aspect of the forgoing embodiments and aspects thereof, the metal-containing material includes tantalum. In a further aspect of the forgoing embodiments and aspects thereof, the metal-containing material includes tungsten.

In a further aspect of the forgoing embodiments and aspects thereof, the metal-containing material includes titanium nitride or tantalum nitride. In a further aspect of the forgoing embodiments and aspects thereof, the metal-containing material includes titanium nitride. In a further aspect of the forgoing embodiments and aspects thereof, the metal-containing material includes tantalum nitride.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

The thermal vapor-phase etch process includes repeated cycles of exposing the material to be etched to different vapor-phase reactants in a vacuum chamber. After each exposure, the chamber is purged by inert gas to remove excess reactants and reaction products.

The following Examples were performed in an ALD system with a showerhead lid which was heated to 130° C. This ALD system has capability to accommodate up to 300 mm diameter wafer sizes. This ALD system has a heated pedestal upon which the wafer is disposed.

Thionyl chloride, isobutyric acid, and propionic acid were obtained from MilliporeSigma. Thionyl chloride was maintained in a stainless-steel ampule at 30° C. Propionic acid was maintained in a stainless-steel ampule at 40° C. Isobutyric acid was maintained in a stainless-steel ampule at 50° C.

In all Examples, test substrates were prepared by physical vapor deposition (PVD) atop silicon wafers or pieces which were all covered with about 3000 Å of thermally grown SiO₂ prior to metal deposition. Co was deposited evenly atop a 200 mm silicon wafer. Mo was deposited as circular spots (45 mm diameter) atop a 300 mm silicon wafer. The wafers were subsequently cleaved into 44 mm×44 mm coupons, with the center of each PVD spot at the center of each coupon. Ni was deposited evenly atop 44 mm×44 mm silicon coupons. In all cases, the deposited metal film thicknesses were about 200 Å. The 44 mm×44 mm coupons were loaded onto 300 mm carrier wafers for ALE processing. Sample thicknesses were measured using X-ray fluorescence. Sample resistances were measured using a four-point probe, and metal resistivities were calculated from the sample resistance and the film thickness.

### Experimental Conditions:

| Step | Conditions |
|---|---|
| (a) | One 5-second dose of thionyl chloride |
| | vapor, diluted in 1200 sccm of argon, with |
| | the chamber pressure maintained at 2000 mTorr. |
| (b) | A first reactor purge of about 2000 sccm |
| | of argon for 60 seconds. |
| (i) | One 20-second dose of either isobutyric |
| | acid vapor or propionic acid vapor, |
| | delivered by flowing 100 sccm of argon |
| | through the ampule containing the |
| | acid. The dose was further diluted by |
| | 500 sccm of argon, with the chamber |
| | pressure maintained at 2000 mTorr. |
| (ii) | A second reactor purge of about 2000 |
| | sccm of argon for 60 seconds. |

### Example 1: ALE of Co, Ni, and Mo by Thionyl Chloride and Propionic Acid

20, 40, or 60 ALE cycles were performed with the process chamber pedestal heater set at 325° C., corresponding to a calibrated sample temperature of about 310° C. In step (i), propionic acid was dosed. Results are shown in the Tables below. Co, Ni, and Mo are etched by more than 0.5 Å/cycle. Co and Mo experience etch delays, while Ni shows greater etch per cycle during the first few ALE cycles. The etch process results in decreased resistivity for Co, likely due in part to thermal annealing of the film, and a slight decrease in resistivity for Mo.

| Metal | Co | Ni | Mo |
|---|---|---|---|
| Amount etched after 20 ALE cycles (Å) | 4 | 22 | 11 |
| Amount etched after 40 ALE cycles (Å) | 14 | 38 | 30 |
| Amount etched after 60 ALE cycles (Å) | 34 | 54 | 47 |
| Etch per cycle (linear fit, Å/cycle) | 0.76 | 0.80 | 0.91 |
| Etch delay (cycles) | 17 | −8 | 8 |

| Metal | Co | Mo |
|---|---|---|
| Resistivity (no etch) | 33-34 | 21-22 |
| Resistivity after 20 ALE cycles (μohm-cm) | 24 | 20 |
| Resistivity after 40 ALE cycles (μohm-cm) | 26 | 20 |

### Example 2: ALE of Co, Ni, and Mo by Thionyl Chloride and Isobutyric Acid

20, 40, or 60 ALE cycles were performed with the process chamber pedestal heater set at 325° C., corresponding to a calibrated sample temperature of about 310° C. In step (i), isobutyric acid was dosed. Results are shown in the Tables below. Co, Ni, and Mo are etched by more than 0.5 Å/cycle, with an etch delay of about 10 cycles for Co. The etch process results in decreased resistivity for Co, likely due in part to thermal annealing of the film, and a slight decrease in resistivity for Mo.

| Metal | Co | Ni | Mo |
|---|---|---|---|
| Amount etched after 20 ALE cycles (Å) | 6 | 14 | 8 |
| Amount etched after 40 ALE cycles (Å) | 20 | 32 | 23 |
| Amount etched after 60 ALE cycles (Å) | 31 | 42 | 30 |
| Etch per cycle (linear fit, Å/cycle) | 0.63 | 0.69 | 0.53 |
| Etch delay (cycles) | 10 | −2 | 2 |

| Metal | Co | Mo |
|---|---|---|
| Resistivity (no etch) | 30-35 | 21-22 |
| Resistivity after 20 ALE cycles (μohm-cm) | 21 | 21 |
| Resistivity after 40 ALE cycles (μohm-cm) | 29 | 20 |
| Resistivity after 60 ALE cycles (μohm-cm) | 34 | 21 |

### Example 3: Thermal Vapor-Phase Etch of Native Oxides

In a prophetic example, test substrates including an exposed thin film of Co, Ni, Cu, Mo, Ru, W, TiN, and/or TaN may be disposed in a thermal etch chamber. These test substrates may have undergone conditioning which results in the formation of a metal compound at the surface. The conditioning may consist of air exposure, which may form a native oxide on the metal surface, or an engineered conditioning, such as a chemical treatment in a prior process which results in conversion of the surface metal to a metal compound. A thermal vapor-phase etch process consisting of process steps (i) and (ii) described above may be repeated between 1 and about 100 times to selectively remove the metal compound, leaving a metal surface which is substantially free of the metal compound. The volatilizer may include propionic acid, isobutyric acid, pivalic acid, or any combination thereof.

As shown above, the vapor-phase etch processes described herein, including the ALE processes described herein, can be readily controlled (i.e., tailored) to provide a specific amount of etch for desired applications. The choice of surface modification agent, volatilizing agent, process temperature, process pressure, and dilution flow may be tuned to modify the etch amount per cycle and/or the selectivity of the process, i.e., to etch one material or subset of materials exposed to the etch process with minimal effect on other exposed materials.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. A process for etching a metal-containing material from a surface of a substrate, the steps comprising:
a Volatilization Step comprising:
(i) exposing the metal-containing material to one or more volatilizing agents comprising one or more halogen-free organic acids selected from the group of propionic acid, isobutyric acid, pivalic acid, acetic acid, butanoic acid, acrylic acid, methacrylic acid, 2-methylbutanoic acid, 3-methylbutanoic acid, 3-butenoic acid, cyclopropanecarboxylic acid, pentanoic acid, (2E)-but-2-enoic acid and (Z)-2-butenoic acid to produce a volatile byproduct from the metal-containing material,
(ii) a purge; and
optionally a Surface Modification Step comprising:
(a) exposing the metal-containing material to one or more surface modification agents comprises one or more chlorinating agent to form a metal-containing material that is different than the metal-containing material prior to exposure to the one or more surface modification agents; and
(b) a purge.

2. The process of claim 1 comprising the Volatilization Step and the Surface Modification Step.

3. The process of claim 1 comprising the Volatilization Step and the Surface Modification Step, wherein the Volatilization Step precedes the Surface Modification Step.

4. The process of claim 1 comprising the Volatilization Step and the Surface Modification Step, wherein the Surface Modification Step precedes the Volatilization Step.

5. The process of claim 1, wherein the metal comprises one or more of Co, Ni, Cu, Mo, Ru, W, TiN and TaN.

6-15. (canceled)

16. The process of claim 1, wherein in step (a) the one or more chlorinating agents is selected from the group of SOCl₂, Cl₂, BCl₃, HCl and TiCl₄.

17. The process of claim 1, wherein in step (a) the one or more chlorinating agent comprises SOCl₂.

18-21. (canceled)

22. The process of claim 1, wherein in step (a) the one or more surface modification agents is dosed as a plasma or a component of a plasma.

23. (canceled)

24. The process of claim 1, wherein in step (a) exposure time of the one or more surface modification agents is from about 0.5 seconds to about 30 seconds.

25-32. (canceled)

33. The process of claim 1, wherein in step (a) one or more surface modification agents is flowed at from about 100 sccm to about 5000 sccm

34. The process of claim 1, wherein the step (a) is carried out at a pressure from about 0.5 torr to about 100 torr.

35. (canceled)

36. (canceled)

37. The process of claim 1, wherein in step (i) the one or more one or more volatilizing agents comprises one or more halogen-free organic acids selected from the group of propionic acid, isobutyric acid, pivalic acid and combinations thereof.

38-51. (canceled)

52. The process of claim 1, wherein in step (i) exposure time of the one or more volatilizing agents is from about 0.5 seconds to about 30 seconds.

53-59. (canceled)

60. The process of claim 1, wherein in step (i) one or more volatilizing agents is flowed at from about 1 seem to about 500 sccm.

61. The process of claim 1, wherein the step (i) is carried out at a pressure from about 0.05 torr to about 10 torr.

62. The process of claim 1, wherein the process comprises about 100 5 to about 1000 cycles.

63-98. (canceled)
